(19) United States
(12) Patent Application Publication
(10) Pub. No.: US 2026/0197989 A1
(43) Pub. Date: Jul. 9, 2026

(54) MEMORY DEVICE AND MANUFACTURING METHOD THEREOF

(71) Applicant: NANYA TECHNOLOGY CORPORATION, New Taipei City (TW)

(72) Inventors: Tsung Chin HSU, New Taipei City (TW); An Jie CHEN, New Taipei City (TW)

(21) Appl. No.: 19/012,881

(22) Filed: Jan. 8, 2025

(51) Int. Cl. H10B 12/00

(52) U.S. Cl. CPC H10B 12/033; H10B 12/315

(57) ABSTRACT

A manufacturing method of a capacitor includes forming a dielectric layer stack over a substrate, forming an opening through the dielectric layer stack, forming a bottom electrode layer lining the opening, forming a protective layer sealing the opening, in which forming the protective layer includes performing a first deposition process to form a first dielectric layer by using a nitrogen plasma, and performing a second deposition process to form a second dielectric layer by using an oxygen plasma, removing the hard mask layer and the protective layer until the top surface of the dielectric layer stack is exposed, and a portion of the protective layer remains in place, forming a high-k dielectric layer along a sidewall of the bottom electrode layer and a sidewall of the protective layer, and forming a top electrode layer along a sidewall of the high-k dielectric layer.

### BACKGROUND

### Field of Disclosure

The present disclosure relates to a memory device and a manufacturing method thereof.

### Description of Related Art

With the shrinking of dimension in capacitors of dynamic random access memory (DRAM), the stability of the capacitors becomes the key factor to influence the electrical properties. To reduce the bowing bias of the capacitors to reduce the short circuit between the capacitors, a hard mask layer may be first formed to define the space of filling the material of the capacitors, and a bottom electrode layer is deposited to fix the critical dimension of the capacitor. Subsequently, a protection layer may be formed over the bottom electrode layer to prevent the bottom electrode layer from being damaged by the subsequent processes. However, the formation of the protection layer may affect the properties of the bottom electrode layer, and will lead to several problems in the subsequent processes.

### SUMMARY

Some embodiments of the present disclosure provide a manufacturing method of a capacitor, including forming a dielectric layer stack over a substrate, forming an opening through the dielectric layer stack to expose a contact in the substrate, forming a bottom electrode layer lining the opening, forming a protective layer sealing the opening, in which forming the protective layer includes performing a first deposition process to form a first dielectric layer by using a nitrogen plasma, and performing a second deposition process to form a second dielectric layer by using an oxygen plasma, removing the hard mask layer and the protective layer until the top surface of the dielectric layer stack is exposed, and a portion of the protective layer remains in place, forming a high-k dielectric layer along a sidewall of the bottom electrode layer and a sidewall of the protective layer, and forming a top electrode layer along a sidewall of the high-k dielectric layer.

In some embodiments, the first dielectric layer is oxidized during the second deposition process.

In some embodiments, the first deposition process includes providing a first precursor gas and the nitrogen plasma, and the second deposition process comprises providing a second precursor gas and the oxygen plasma.

In some embodiments, the first precursor and the second precursor are the same.

In some embodiments, a RF power of the oxygen plasma is lower than a RF power of the nitrogen plasma.

In some embodiments, a nitrogen concentration of the first dielectric layer is higher than a nitrogen concentration of the second dielectric layer.

In some embodiments, an oxygen concentration of the first dielectric layer is lower than an oxygen concentration of the second dielectric layer.

In some embodiments, a silicon concentration of the first dielectric layer is higher than a silicon concentration of the second dielectric layer.

In some embodiments, the first deposition process and the second deposition process are performed in the same chamber.

In some embodiments, the high-k dielectric layer is free of nitrogen.

Some embodiments of the present disclosure provides a capacitor including a bottom electrode layer, a nitrogen-containing layer, a high-k dielectric layer, and a top electrode layer. The nitrogen-containing layer is in contact with an upper portion of the bottom electrode layer. The high-k dielectric layer is along a sidewall of the bottom electrode and a sidewall of the nitrogen-containing layer, in which a lower portion of the high-k dielectric layer is in contact with the bottom electrode layer, and an upper portion of the high-k dielectric layer is in contact with the nitrogen-containing layer. The top electrode layer along a sidewall of the high-k dielectric layer.

In some embodiments, the nitrogen-containing layer includes a first dielectric layer in contact with the bottom electrode layer and a second dielectric layer between the first dielectric layer and the high-k dielectric layer, and a nitrogen concentration of the first dielectric layer is higher than a nitrogen concentration of the second dielectric layer.

In some embodiments, an oxygen concentration of the first dielectric layer is lower than an oxygen concentration of the second dielectric layer.

In some embodiments, a silicon concentration of the first dielectric layer is higher than a silicon concentration of the second dielectric layer.

In some embodiments, a carbon concentration of the first dielectric layer is higher than a carbon concentration of the second dielectric layer.

In some embodiments, a nitrogen concentration of the high-k dielectric layer is lower than a nitrogen concentration of the nitrogen-containing layer.

In some embodiments, the high-k dielectric layer is free of nitrogen.

In some embodiments, the capacitor further includes a plurality of supporting layers arranged from bottom to top and in contact with the bottom electrode layer, in which the supporting layers and the nitrogen-containing layer are at opposite sides of the bottom electrode layer.

In some embodiments, a bottom of the nitrogen-containing layer is lower than a top surface of a topmost one of the supporting layers.

In some embodiments, a thickness of the nitrogen-containing layer decreases toward to the substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of the memory device.

FIGS. 2-11 illustrate cross-section views of intermediate stages of a manufacturing process of a capacitor according to some embodiments of the present disclosure.

FIG. 12 illustrates cross-section view of the capacitor taken along section A-A′ in FIG. 11.

FIG. 13 illustrates cross-section view of the capacitor taken along section B-B′ in FIG. 11.

### DETAILED DESCRIPTION

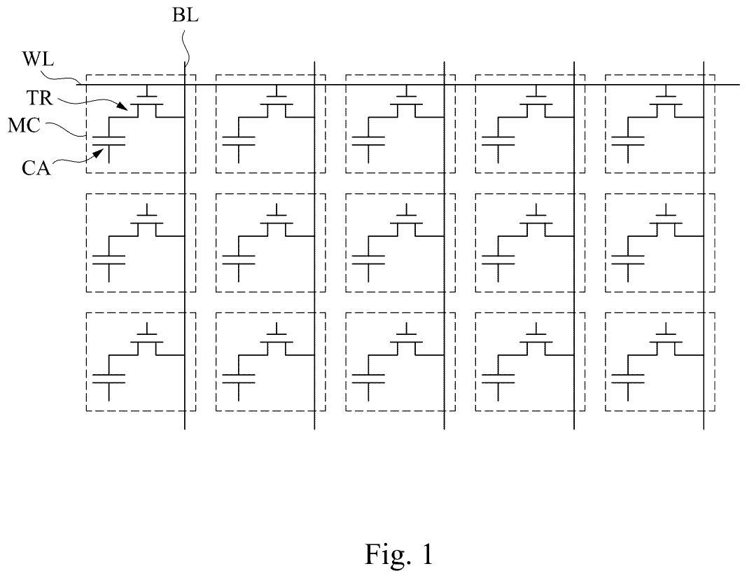

FIG. 1 illustrates a circuit diagram of the memory device. Referring to FIG. 1, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. The capacitor CA is electrically connected to a source/drain region of the transistor TR, a bit line BL is electrically connected to the other source/drain region of the transistor TR, and a word line WL is electrically connected to a gate region of the transistor TR. In the present disclosure, we focus on the manufacturing process of the capacitors. The manufacturing process of the word lines, the transistors and the bit lines will not be mentioned in the present disclosure.

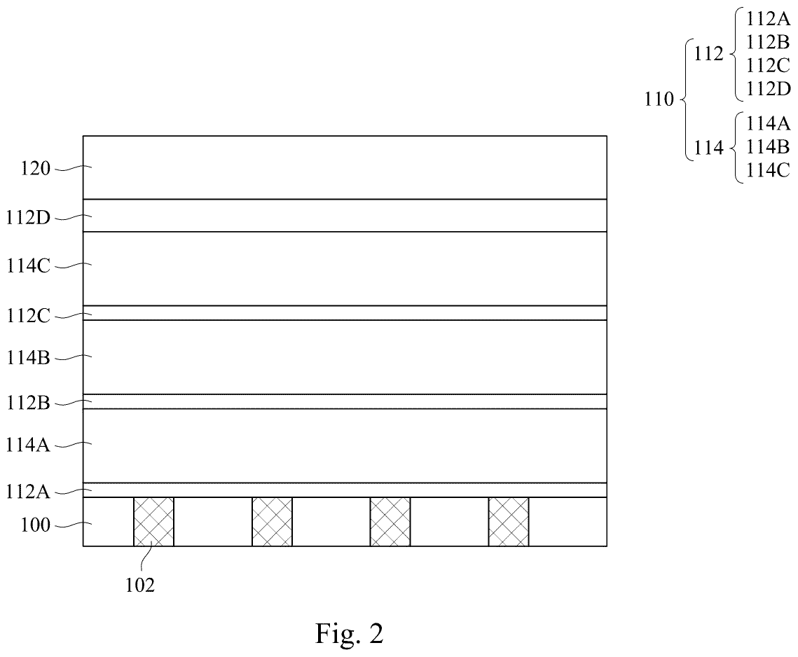

FIGS. 2-11 illustrate cross-section views of intermediate stages of a manufacturing process of a memory device according to some embodiments of the present disclosure. Referring to FIG. 2, a dielectric layer stack 110 is formed over a substrate 100. The substrate 100 may be a dielectric layer with contacts 102 formed therein. The contacts 102 may be electrically connected with the underlying components, such as transistors. Forming the dielectric layer stack 110 includes alternately forming a plurality of supporting layers 112 and molding layers 114 over the substrate 110. The topmost and the bottom most layer of the dielectric layer stack 110 are the supporting layers 112, and each of the molding layers 114 are between two of the adjacent supporting layers 112. The supporting layers 112 and the molding layers 114 are made of different materials. In some embodiments, the supporting layers 112 are made of silicon nitride, and the molding layers 114 are made of silicon oxide. The number of the supporting layers 112 and the molding layers 114 are not limited in the present disclosure. In some embodiments, the dielectric layer stack 110 includes four supporting layers 112A, 112B, 112C and 112D, and three molding layers 114A, 114B, and 114C.

Subsequently, a hard mask layer 120 is formed over the dielectric layer stack 100. The hard mask layer 120 is in contact with the topmost supporting layer 114D of the supporting layers 114. In some embodiments, the hard mask layer 120 is made of polysilicon.

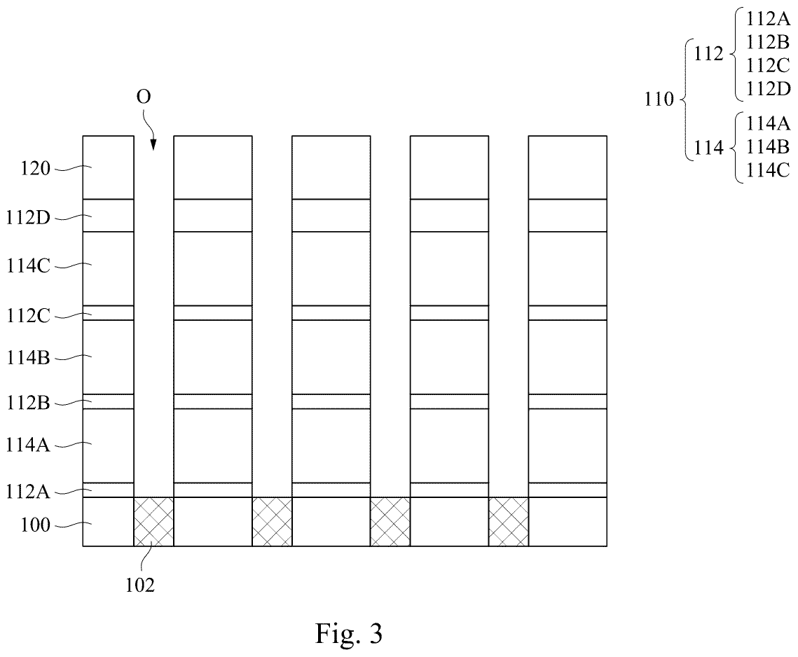

Referring to FIG. 3, the hard mask layer 120 is patterned, and openings O are formed through the dielectric layer stack 110 to expose the contacts 102 in the substrate 100 by using the hard mask layer 120 as mask. The openings O are formed by any suitable methods, such as dry etching.

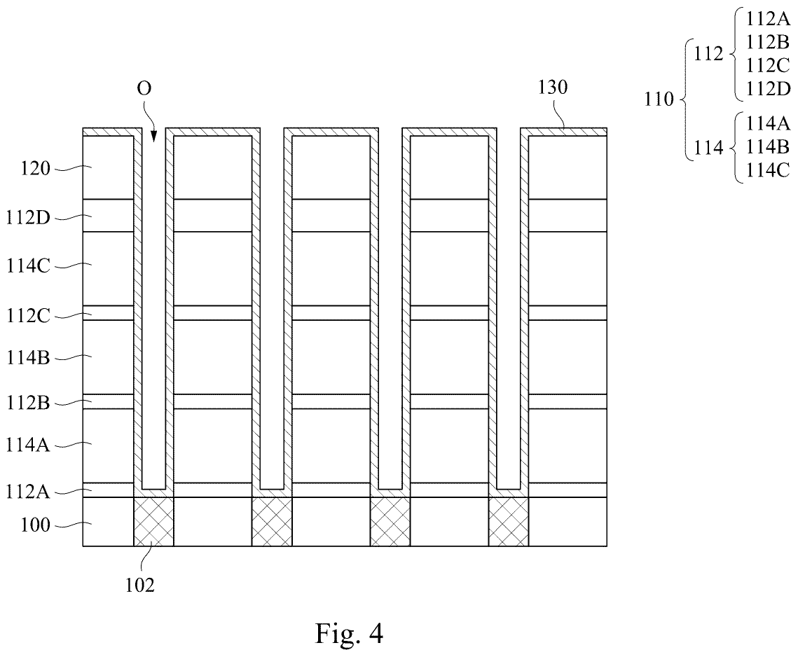

Referring to FIG. 4, a bottom electrode layer 130 is formed lining the openings O. The bottom electrode layer 130 is in contact with the contacts 102, extends along the sidewall of the openings O to the top surface of the hard mask layer 120. The bottom electrode layer 130 may be formed by any suitable method, such as chemical vapor deposition, atomic layer deposition, or the like. The bottom electrode layer 130 may be made of conductive material, such as TaN, W, TiN, Ru, Pt.

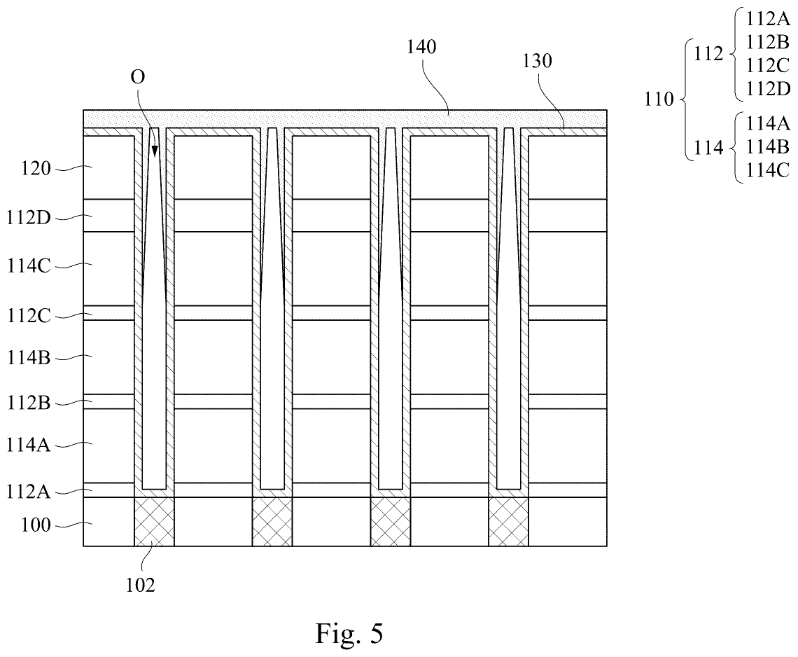

Referring to FIG. 5, a nitrogen-containing layer 140 is formed to seal the openings O. In some embodiments, the nitrogen-containing layer 140 can also be referred to as a protective layer. The nitrogen-containing layer 140 is used to protect the bottom electrode layer 130 from being damaged by the subsequent process, and the formation of the nitrogen-containing layer 140 itself does not change the properties of the nitrogen-containing layer 140. The nitrogen-containing layer 140 is over the hard mask layer 120, and extends into the openings O. The nitrogen-containing layer 140 only seals the openings O, and thus only a portion of the openings O are occupied by the nitrogen-containing layer 140. The remaining portions of the openings O not being occupied by the nitrogen-containing layer 140 forms air gaps. In some embodiments, the bottom of the nitrogen-containing layer 140 is lower than a top surface of the dielectric layer stack 110, and a portion of the nitrogen-containing layer 140 is along a sidewall of the bottom electrode layer 130. In some embodiments, the thickness of the nitrogen-containing layer 140 decreases toward the substrate 100.

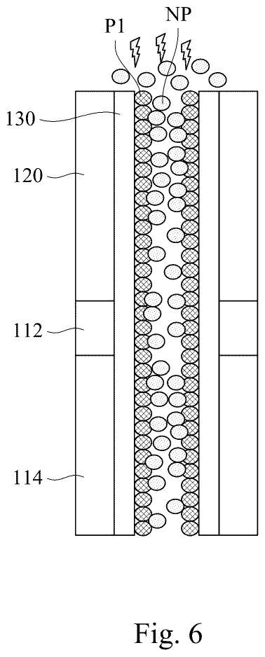

FIGS. 6-8 illustrate a detailed process of forming the nitrogen-containing layer 140 in some embodiments of the present disclosure. Referring to FIG. 6, a first deposition process is performed to form a dielectric layer 142 along a sidewall of the bottom electrode layer 130 by using a nitrogen plasma NP. Specifically, the first deposition process includes providing a first precursor gas P1 and the nitrogen plasma NP. In some embodiments, the first precursor gas P1 may be one or more selected from a group containing SiCl₄, aminosilane, and silanol. In some embodiments, purge gas is provided after providing first precursor gas P1 and the nitrogen plasma NP. That is, the first deposition process may include a plurality of cycles providing the first precursor gas P1, the purge gas, the nitrogen plasma NP, and the purge gas. In some embodiments, the purge gas may be argon and nitrogen. In some embodiments, the RF power of the nitrogen plasma NP is between 150 W and 250 W. Since the formation of the dielectric layer 142 includes providing the nitrogen plasma NP, the resulting dielectric layer 142 contains nitrogen, and the properties of the dielectric layer 142 is like silicon nitride. In some embodiments, the chemical formula of the dielectric layer 142 may be represented by Si_{K}C_{X}N_{Y}H_{Z}.

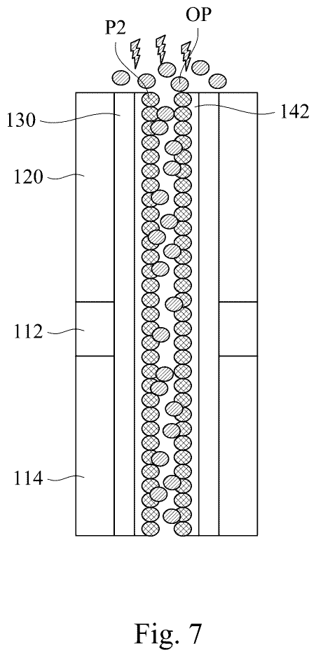

Referring to FIG. 7, a second deposition process is performed to form a dielectric layer 144 along a sidewall of the dielectric layer 142 by an oxygen plasma OP. Specifically, the second deposition process includes providing a second precursor gas P2 and the oxygen plasma OP. The second precursor gas P2 and the oxygen plasma OP are used to form the dielectric layer 144, and the oxygen plasma OP may further oxidize the dielectric layer 142. In some embodiments, the second precursor gas P2 may be one or more selected from a group containing SiCl₄, aminosilane, and silanol. In some embodiments, the first precursor P1 and the second precursor P2 are the same. In some embodiments, purge gas is provided after providing second precursor gas P2 and the oxygen plasma OP. That is, the second deposition process may include a plurality of cycles providing the second precursor gas P2, the purge gas, the oxygen plasma OP, and the purge gas. In some embodiments, the purge gas may be argon and nitrogen. In some embodiments, the RF power of the oxygen plasma OP is lower than the RF power of the nitrogen plasma NP, such that the oxygen plasma OP only oxidizes the dielectric layer 142 and does not oxidize the bottom electrode layer 130. Therefore, the hardness of the bottom electrode layer 130 is not affected by the second deposition process, and the wiggling issue of the capacitor caused by the reduction of the hardness of the bottom electrode layer 130 is reduced. In some embodiments, the RF power of the oxygen plasma OP is between 30 W and 50 W.

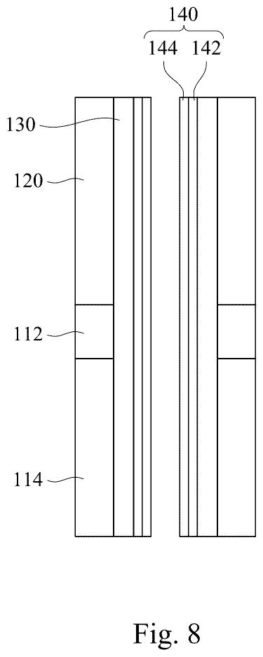

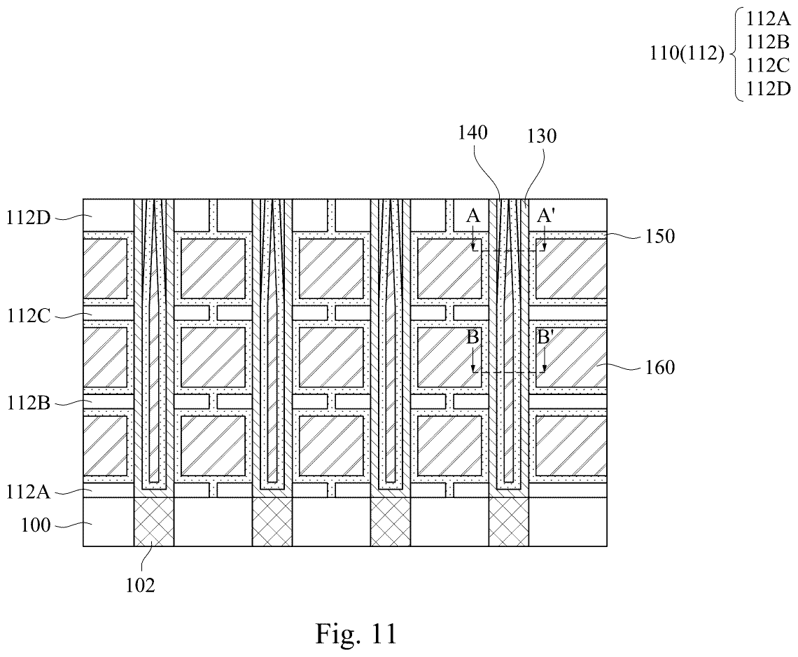

Referring to FIG. 8, after the second deposition process is complete, the dielectric layer 142 is oxidized, and the dielectric layer 144 is formed along the sidewall of the dielectric layer 142. The nitrogen-containing layer 140 includes the dielectric layer 142 in contact with the bottom electrode layer 130 and a dielectric layer 144 between the dielectric layer 142 and the high-k dielectric layer (such as high-k dielectric layer 150 in FIG. 11) formed in the subsequent process.

Since the formation of the dielectric layer 144 includes providing the oxygen plasma OP, the dielectric layer 142 being oxidized and the dielectric layer 144 contain oxygen. In some embodiments, the chemical formula of the dielectric layer 142 after being oxidized may be represented by Si_{K}O_{L}C_{X}N_{Y}H_{Z}, and the chemical formula of the dielectric layer 144 may be represented by SiₓO_{y}. In some embodiments, the nitrogen concentration of the dielectric layer 142 is higher than the nitrogen concentration of the dielectric layer 144, the oxygen concentration of the dielectric layer 142 is lower than the oxygen concentration of the dielectric layer 144, the silicon concentration of the dielectric layer 142 is higher than the silicon concentration of the dielectric layer 144, and the carbon concentration of the dielectric layer 142 is higher than the carbon concentration of the dielectric layer 144. In some embodiments, the silicon concentration of the dielectric layer 142 is between 69% and 79%, the oxygen concentration of the dielectric layer 142 is between 20% and 30%, the nitrogen concentration of the dielectric layer 142 is between 4% and 13%, and carbon concentration of the dielectric layer 142 is between 1% and 3%. The silicon concentration of the dielectric layer 144 is between 61% and 74%, the oxygen concentration of the dielectric layer 144 is between 25% and 38%, the nitrogen concentration of the dielectric layer 144 is between 0.12% and 0.23%, and carbon concentration of the dielectric layer 144 is between 0.15% and 0.25%. In some embodiments, the thickness of the dielectric layer 142 is between 10 Å and 25 Å, and the thickness of the dielectric layer 144 is between 95 Å and 125 Å. The first deposition process used for forming the dielectric layer 142 (FIG. 6) and the second deposition process used for oxidizing the dielectric layer 142and forming the dielectric layer 144 are performed in the same chamber, and thus the process of forming the nitrogen-containing 140 may be simplified.

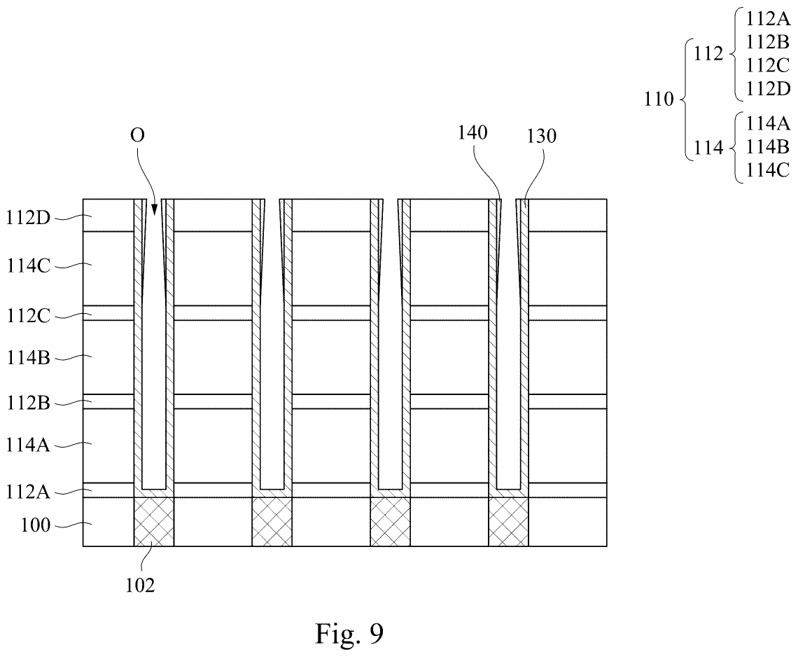

Referring to FIG. 9, the hard mask layer 120 and the nitrogen-containing layer 140 are removed until the top surface of the dielectric layer stack 110 is exposed, and a portion of the nitrogen-containing layer 140 remains in place. The openings O are not sealed by the nitrogen-containing layer 140 after the top surface of the dielectric layer stack 110 is exposed. Specifically, a planarization process may be performed to remove the hard mask layer 120 and the nitrogen-containing layer 140 over the dielectric layer stack 110 until the top surface of the dielectric layer stack 110 is exposed. The nitrogen-containing layer 140 prevents the bottom electrode layer 130 from being damaged by the planarization process. For example, the formation of the nitrogen-containing layer 140 does not oxidize the bottom electrode layer 130, so the hardness of the nitrogen-containing layer 140 does not decrease due to the oxidation of the bottom electrode layer 130. Therefore, the bottom electrode layer 130 does not suffer wobbling issue during the planarization process. In some embodiments, the wobbling issue of the bottom electrode layer 130 may aggravate the short circuit between capacitors. After the planarization process is complete, the nitrogen-containing layer 140 lower than the top surface of the dielectric layer stack 110 remains in place.

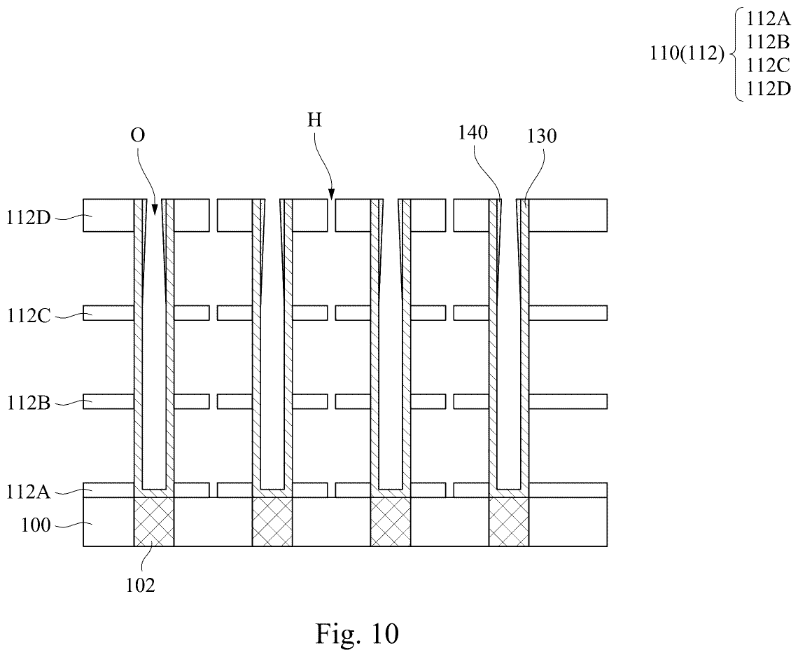

Referring to FIG. 10, the molding layers 114 are removed by a wet etching process. Specifically, holes H may be formed through some of the supporting layers 112, and thus the etchant is able to remove the molding layers 114 between the supporting layers 112. Since the molding layers 114 and the supporting layers 112 are made of different materials, a suitable etchant may be used to remove the molding layers 114, while the supporting layers 112 keep substantially intact. After the molding layers 114 are removed, the bottom electrode layer 130, the supporting layers 114, and the nitrogen-containing layer 140 remain in place. The bottom electrode layer 130 connects the supporting layers 114, and the nitrogen-containing layers 140 are along an upper portion of the bottom electrode layer 130. The nitrogen-containing layer 140 may also be used to prevent the bottom electrode layer 130 from being damaged by the etching process of removing the molding layers 114. Since the nitrogen-containing layer 140 and the molding layers 114 are made of different materials or the composition between the nitrogen-containing layer 140 and the molding layers 114 are different, the nitrogen-containing layer 140 keep substantially intact during removing the molding layers 114.

Referring to FIG. 11, a high-k dielectric layer 150 is formed lining the openings O and the spaces between the supporting layers 112, and a top electrode layer 160 is formed overfilling the remaining portions in the openings O and the spaces between the supporting layers 112. Subsequently, excess portion of the high-k dielectric layer 150 and the top electrode layer 160 is removed by the planarization process until the top surface of the topmost supporting layer 112 is exposed. Therefore, the high-k dielectric layer 150 is formed along the sidewall of the bottom electrode layer 130 and the sidewall of the nitrogen-containing layer 140, and the top electrode layer 160 is formed along the sidewall of the high-k dielectric layer 150. Since the hardness of the bottom electrode layer 130 is not affected by the formation of the nitrogen-containing layer 140 in the previous stage, the bottom electrode layer 130 does not suffer wobbling issue during forming the high-k dielectric layer 150 and top electrode layer 160. In some embodiments, the wobbling issue of the bottom electrode layer 130 may aggravate the short circuit between capacitors. In some embodiments, the nitrogen concentration of the high-k dielectric layer 150 is lower than the nitrogen concentration of the nitrogen-containing layer 140. In some embodiments, the high-k dielectric layer 150 is free of nitrogen. The high-k dielectric layer 150 may be made of ZrO₂, or HfO₂, and the top electrode layer 160 may be made of conductive material, such as TaN, W, TiN, Ru, Pt. After forming the high-k dielectric layer 150, the dielectric layer 144 (FIG. 7) of the nitrogen-containing layer 140 is in contact with the high-k dielectric layer 150 and between the dielectric layer 146 of the nitrogen-containing layer 140 and the high-k dielectric layer 150.

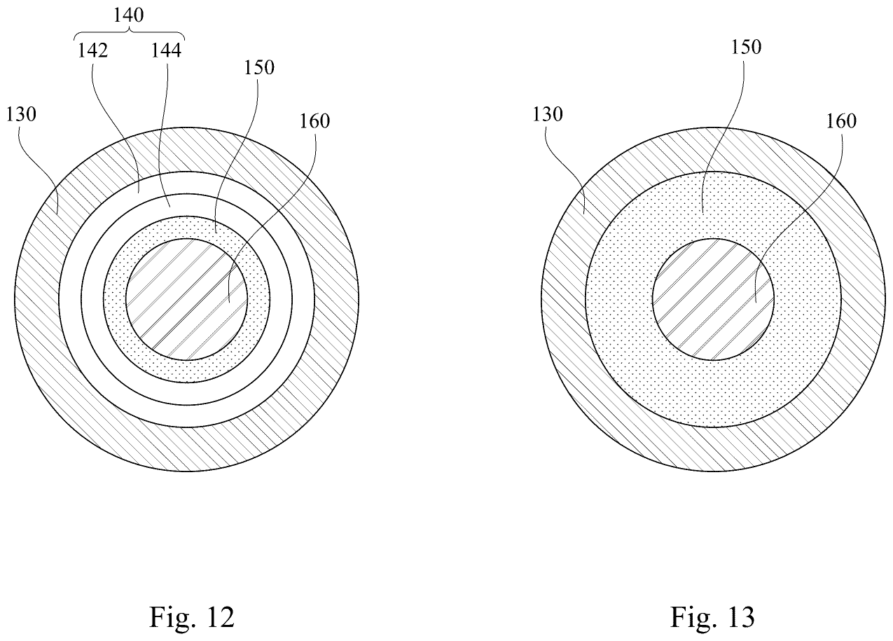

The resulting memory device is illustrated in FIG. 11. Moreover, FIG. 12 illustrates a top view of the memory device along line A-A′ in FIG. 11. FIG. 13 illustrates a top view of the memory device along line B-B′ in FIG. 11. Referring to FIGS. 11-13, the memory device includes a substrate 100 and a capacitor. The capacitor is over the substrate 100. The capacitor includes a bottom electrode layer 130, a nitrogen-containing layer 140, a high-k dielectric layer 150, and a top electrode layer 160. The nitrogen-containing layer 140 is in contact with an upper portion of the bottom electrode layer 130. The high-k dielectric layer 150 is along a sidewall of the bottom electrode 130 and a sidewall of the nitrogen-containing layer 140, in which a lower portion of the high-k dielectric layer 150 is in contact with the bottom electrode layer 130, and an upper portion of the high-k dielectric layer 150 is in contact with the nitrogen-containing layer 140. The top electrode layer 160 is along a sidewall of the high-k dielectric layer 150. The nitrogen-containing layer 140 includes a dielectric layer 142 and a dielectric layer 144. The dielectric layer 142 is in contact with the bottom electrode layer 130 and the dielectric layer 144 is between the dielectric layer 142 and the high-k dielectric layer 150. Stated another way, at a first top view taken along line A-A′, the top electrode layer 160 may be surrounded by the high-k dielectric layer 150. The high-k dielectric layer 150 may be surrounded by the dielectric layer 144 of the nitrogen-containing layer 140. The dielectric layer 144 of the nitrogen-containing layer 140 may be surrounded by the dielectric layer 142 of the nitrogen-containing layer 140. The dielectric layer 142 of the nitrogen-containing layer 140 may be surrounded by the bottom electrode layer 130. The high-k dielectric layer 150 may be in contact with the nitrogen-containing layer 140. At a second top view below the first top view taken along line B-B′, the top electrode layer 160 may be surrounded by the high-k dielectric layer 150. The high-k dielectric layer 150 may be surrounded by the bottom electrode layer 130. The high-k dielectric layer 150 may be in contact with the bottom electrode layer 130.

The capacitor further includes a plurality of supporting layers 112 arranged from bottom to top and in contact with the bottom electrode layer 130, and the supporting layers 112 and the nitrogen-containing layer 140 are at opposite sides of the bottom electrode layer 130. The bottom of the nitrogen-containing layer 140 is lower than a top surface of a topmost one of the supporting layers 112, such as supporting layer 112D.

The nitrogen-containing layer 140 in the capacitor may be used to prevent the bottom electrode layer 130 from being damaged by the planarization process and etching process during forming the capacitor. The bottom electrode layer 130 in the present disclosure has high hardness after the nitrogen-containing layer 140 is formed. Therefore, the bottom electrode layer 130 does not suffer wobbling issue during the manufacturing process of the capacitor, and the short circuit between capacitors may be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming a dielectric layer stack over a substrate;
forming an opening through the dielectric layer stack to expose a contact in the substrate;
forming a bottom electrode layer lining the opening;
forming a protective layer sealing the opening, wherein forming the protective layer comprises:
performing a first deposition process to form a first dielectric layer by using a nitrogen plasma; and
performing a second deposition process to form a second dielectric layer by using an oxygen plasma;
removing the hard mask layer and the nitrogen-containing layer until the top surface of the dielectric layer stack is exposed, and a portion of the protective layer remains in place;
forming a high-k dielectric layer along a sidewall of the bottom electrode layer and a sidewall of the protective layer; and
forming a top electrode layer along a sidewall of the high-k dielectric layer.

2. The manufacturing method of claim 1, wherein the first dielectric layer is oxidized during the second deposition process.

3. The manufacturing method of claim 1, wherein the first deposition process comprises providing a first precursor gas and the nitrogen plasma, and the second deposition process comprises providing a second precursor gas and the oxygen plasma.

4. The manufacturing method of claim 3, wherein the first precursor and the second precursor are the same.

5. The manufacturing method of claim 3, wherein a RF power of the oxygen plasma is lower than a RF power of the nitrogen plasma.

6. The manufacturing method of claim 1, wherein a nitrogen concentration of the first dielectric layer is higher than a nitrogen concentration of the second dielectric layer.

7. The manufacturing method of claim 1, wherein an oxygen concentration of the first dielectric layer is lower than an oxygen concentration of the second dielectric layer.

8. The manufacturing method of claim 1, wherein a silicon concentration of the first dielectric layer is higher than a silicon concentration of the second dielectric layer.

9. The manufacturing method of claim 1, wherein the first deposition process and the second deposition process are performed in the same chamber.

10. The manufacturing method of claim 1, wherein the high-k dielectric layer is free of nitrogen.

11. A memory device, comprising:
a substrate; and
a capacitor over the substrate and comprising:
a bottom electrode layer;
a nitrogen-containing layer in contact with an upper portion of the bottom electrode layer;
a high-k dielectric layer along a sidewall of the bottom electrode and a sidewall of the nitrogen-containing layer, wherein a lower portion of the high-k dielectric layer is in contact with the bottom electrode layer, and an upper portion of the high-k dielectric layer is in contact with the nitrogen-containing layer; and
a top electrode layer along a sidewall of the high-k dielectric layer.

12. The memory device of claim 11, wherein the nitrogen-containing layer comprises a first dielectric layer in contact with the bottom electrode layer and a second dielectric layer between the first dielectric layer and the high-k dielectric layer, and a nitrogen concentration of the first dielectric layer is higher than a nitrogen concentration of the second dielectric layer.

13. The memory device of claim 12, wherein an oxygen concentration of the first dielectric layer is lower than an oxygen concentration of the second dielectric layer.

14. The memory device of claim 12, wherein a silicon concentration of the first dielectric layer is higher than a silicon concentration of the second dielectric layer.

15. The memory device of claim 12, wherein a carbon concentration of the first dielectric layer is higher than a carbon concentration of the second dielectric layer.

16. The memory device of claim 11, wherein a nitrogen concentration of the high-k dielectric layer is lower than a nitrogen concentration of the nitrogen-containing layer.

17. The memory device of claim 16, wherein the high-k dielectric layer is free of nitrogen.

18. The memory device of claim 11, further comprising
a plurality of supporting layers arranged from bottom to top and in contact with the bottom electrode layer, wherein the supporting layers and the nitrogen-containing layer are at opposite sides of the bottom electrode layer.

19. The memory device of claim 18, wherein a bottom of the nitrogen-containing layer is lower than a top surface of a topmost one of the supporting layers.

20. The memory device of claim 11, wherein a thickness of the nitrogen-containing layer decreases toward the substrate.
